(19) United States
(12) Patent Application Publication
(10) Pub. No.: US 2001/0036721 A1
(43) Pub. Date: Nov. 1, 2001

(54) Process for metallizing at least one insulating layer of a component

(76) Inventors: Claus Dallner, Steppach (DE); Klaus Lowack, Erlangen (DE); Gunter Schmid, Hemhofen (DE); Recai Sezi, Rottenbach (DE)

Correspondence Address: LERNER AND GREENBERG, P.A., Post Office Box 2480, Hollywood, FL, 33022-2480, US

(21) Appl. No.: 09/817,966

(22) Filed: Mar. 27, 2001

(30) Foreign Application Priority Data
Mar. 27, 2000 (DE) 100 15 213.9

(51) Int. Cl. H01L 21/4763; H01L 21/44

(52) U.S. Cl. 438/618; 438/638; 438/624

(57) ABSTRACT

The invention relates to a process for metallizing at least one insulating layer of a component. A plurality of levels are exposed for metallization by patterning and forming connections between the insulating layers.

### BACKGROUND OF THE INVENTION

Field of the Invention

The invention relates to a process for metallizing at least one insulating layer of a component.

A metal layer on an insulating layer of an electronic or microelectronic component is currently applied by the following process: First, a thin layer of metal is applied to the insulator by a vacuum process. After covering with photoresist and patterning thereof, the metal layer is chemically or electrochemically reinforced, and then the resist is stripped and the first thin metal layer is etched back. This process is complex and expensive. Moreover, the stripping of the resist may lead to the formation of particles and consequently to a reduced yield.

Currently, when forming electrical connections (vias; contact holes) between different conductor tracks and levels of the component, all of the layers have to be treated individually using the configuration described above. The metal coatings on different levels of the component are not formed simultaneously. Published German Patent application DE 198 51 101 A1 discloses a process for the selective deposition of a layer of metal on the surface of a plastic substrate. In this process, the regions of the surface which are to be coated are acted on by electromagnetic radiation, during which process chemical bonds are split and functional groups are created as reactive centers. The irradiation takes place in particular using UV radiation at a wavelength of <320 nm, preferably 222 nm. After the irradiation, which takes place with the aid of a mask or with a writing laser beam, a precious metal connection is fixed to the reactive functional groups at the surface. To do this, the plastic part is either immersed in a swelling solution, for example in a 5-molar aqueous NaOH solution, or is brought into direct contact with a solution which contains the substance to be separated out, i.e. with a nucleating solution. The layer of metal is then deposited in an electroless metallization bath.

A procedure of this nature is not practical in microelectronics, since high-energy radiation, in particular of a wavelength of 222 nm, is required to split the chemical bonds. However, there are no sufficiently powerful lamps of this wavelength, and consequently the exposure times are significantly higher (factor of >10) than with standard exposures. As a result, however, the throughput of nucleatable substrates is considerably restricted, and moreover the excimer UV lamps required are extremely expensive. Moreover, during the splitting of the bonds, low molecular weight fragments are released, which can contaminate the expensive masks. A further drawback of the known process is that it only operates positively, i.e. only the exposed regions can be nucleated. A procedure in negative mode, in which the unexposed regions are nucleated, by contrast, is not possible. This may entail high additional costs for new masks, if, for example, there are only negative masks for existing processes.

To metallize dielectric layers on an electronic component, a process is known from German Patent Application DE 199 57 130.9 (not yet published) in which a photosensitive dielectric is applied to a substrate. The dielectric is exposed in a subsequent working step and is nucleated and metallized either with or without a heat treatment. A drawback of this process is that it is restricted to photosensitive dielectrics.

### SUMMARY OF THE INVENTION

It is accordingly an object of the invention to provide a process for metallizing layers on a component which overcomes the above-mentioned disadvantageous of the prior art processes of this general type. In particular, it is an object of the invention to provide a process for metallizing layers on a component which is compatible with the features of existing process lines, operates in positive and negative mode, is not restricted to photosensitive dielectrics, and which can be used to metallize a plurality of layers of the component simultaneously.

With the foregoing and other objects in view there is provided, in accordance with the invention, a process for metallizing at least one insulating layer of an electronic or microelectronic component, that includes the following steps: Applying at least a first insulating layer to a substrate and, if appropriate, patterning this layer; Applying at least a second insulating layer at least to the first insulating layer; Patterning at least the second insulating layer; If necessary, applying at least a further insulating layer, and if appropriate, patterning the further insulating layer; Selectively activating the exposed and activatable surface; and Nucleating and metallizing the exposed, activated regions.

Accordingly, the process allows at least one level of a component to be metallized, with the two adjoining layers, the first and second insulating layers, being chemically different.

In this context, the terms “first” and “second” insulating layers mean that irrespective of their sequence on the substrate, all of the first insulating layers and all of the second insulating layers can in each case be activated, nucleated and metallized by the same activators. The term “first” or “second” insulating layer accordingly encompasses chemical identity/similarity or an identical behavior of the layer in question (for example the “first” layer) during activation. All of the further insulating layers may be first, second or any other desired insulating layers.

In accordance with an added feature of the invention, after the patterning of the second insulating layer, the exposed surface of the first insulating layer is selectively activated. The activation may also be carried out by various activators at a plurality of levels simultaneously if the surfaces which are to be activated are chemically different.

In accordance with an additional feature of the invention, according to one embodiment, the first insulating layer is also patterned before the second insulating layer is applied, so that contact holes leading to the substrate are formed. The upper insulating layer may or may not be activatable and is patterned. Depending on the activator selected, the treatment with an activator leads to activation of the lower insulating layer, if it is exposed, or of the upper insulating layer. Then, by way of example, a third layer is applied to this layer structure and is patterned. The final activation is followed by the metallization of the activated and exposed surface. If there is a layer structure with more than two layers which are in each case differently patterned, the activation takes place wherever a surface is accessible to the activator and can be activated by the activator.

In this context, the term “insulating layer” or “insulation layer” is understood as meaning an electrically insulating material which remains in the component, i.e. is not removed, after fabrication of the component. Materials which serve as patterning aids and are removed again after a process (e.g. metallization, etching) has been carried out, for example commercial Novolak-based photoresists, are not included under this term. Materials which form part of the substrate (e.g. circuit boards based on epoxy resin) or are used as covering materials (e.g. as a passivation layer on an IC made from silicon oxide and/or silicon nitride or an IC housing made from filled epoxy resin, i.e. mold compound) are also not “insulating layers” in the context of the term as it is used here.

In accordance with another feature of the invention, the thickness of the insulating layer is preferably between 0.05 and 50 μm, particularly preferably between 0.1 and 20 μm. There are activatable and non-activatable insulating layers. The activatable insulating layers are organic or organic element insulators, and the non-activatable insulating layers additionally encompass inorganic insulators. In accordance with a further feature of the invention, each type of insulating layer preferably consists of a polymer. Two insulating layers which adjoin one another, of which one is to be activated, nucleated and metallized, are chemically different. The polymer advantageously has a high chemical and thermal stability. As a result, soldering and cleaning processes as well as the activation (chemical and/or physical) are withstood without damage. Particularly in the case of the activatable insulating layers, it has proven advantageous to use the following types of polymers: Dielectrics such as polyimides, polybenzoxazoles, polybenzimadazoles; predominantly aromatic polyethers, polyether ketones, polyether sulfones; benzocyclobutene, aromatic hydrocarbons, polyquinolines, polyquinoxalines, polysiloxanes (silicones), polyurethanes or epoxy resins. Copolymers or mixtures of these polymers with one another are also suitable. Furthermore, compounds or polymers with an organic-inorganic structure, such as for example organosilicon, organophosphorus or organoboron compounds, are also suitable. It is known that all of the abovementioned classes of materials can be applied either in finished form (centrifuging, screen printing, etc.) or a precursor can be vapor-deposited on the substrate or a lower insulating layer, and the polymer can then be produced. The layers which are produced on the substrate or an insulating layer include, for example, layers of carbon, a-C:H and a-C:H layers (amorphous) with further elements, such as Si, P, O, B. Purely inorganic materials, such as silicon oxide and silicon nitride are also included in the non-activatable insulating layers and are only applied and patterned as an upper layer, for example by a perforated mask, printing technique and/or lithography.

In principle, all materials which are stable under the processes to be carried out, have good electrical insulating properties and have no disruptive effect on the finished component are suitable. Photosensitive formulations of the insulating materials are particularly suitable.

In accordance with yet an added feature of the invention, the insulating layer may also contain a plurality of the abovementioned components and filler. Suitable fillers may be admixed with the insulating material (dielectric) in particular for use as a paste, but also for screen printing. The material can be applied to the substrate, by way of example, in dissolved form or as a paste. Examples of suitable techniques include centrifuging, pouring, dispensing, doctoring, pad printing, ink-jet printing and/or screen printing.

In accordance with yet an additional feature of the invention, an insulating layer is applied to the substrate or an existing insulating layer, for example by a centrifuging technique. The insulating layer is dried and/or heated if this is necessary in order to obtain the final properties. Then, the second insulating layer is applied to the first insulating layer and is again dried if necessary. Then, for example for patterning, it is exposed using a mask, developed and dried and/or heated again. The subsequent treatment of the layer sandwich formed with an activator leads to selective activation either of the upper insulating layer or the lower insulating layer.

In accordance with yet another feature of the invention, the activation can be carried out by dipping, etching, exposure, irradiation, sputtering, heating, partial dissolution, wetting or another known technique.

The activator may in particular also be a combination of a gas with a liquid or some other combination of a plurality of activators. The activation selectively modifies an insulating layer or the surface of an insulating layer, for example in such a manner that subsequently only this layer can be nucleated and/or metallized.

Examples of liquid activators are basic reagents, such as solutions of one or more alkali metal and/or alkaline-earth metal hydroxides, ammonium hydroxides; oxidizing reagents, such as a solution of hydrogen peroxide, chromate, permanganate, (per)chlorate and/or peroxosulfate; solutions which contain an acid, such as sulfuric acid, hydrochloric acid, nitric acid and/or phosphoric acid. The solutions may all be used individually or in any desired combination.

Examples of activators which are present in the form of a plasma are oxygen, chlorine, carbon dioxide, sulfur dioxide, noble gas and/or ammonia plasmas; examples of suitable gases are ozone, oxygen, halogens and/or sulfur dioxide, as well as mixtures thereof.

The substrate is preferably a semiconductor (silicon (Si), galliumarsenide, germanium (Ge)) or a ceramic, with electronic circuits including metal and insulating layers (for example a front-end machined substrate) possibly already being present beneath the first insulating layer. However, the substrate may also be glass, a circuit board and/or metal. Moreover, the substrate may also be one of the abovementioned materials with an applied insulating layer.

The nucleating solution is the solution or emulsion of a metal (or a metal compound) in ionogenic or colloidal form. This solution may be neutral, basic or acidic. Preferred nucleating solutions are all solutions of metals and nonmetals or compounds thereof which catalyze the deposition of a metal from a redox-chemically metastable solution of this metal. Precious metals (ruthenium (Ru), rhodium (Rh), palladium (Pd), osmium (Os), iridium (Ir), platinum (Pt), silver (Ag), gold (Au)) or compounds and complexes (organic and/or inorganic) thereof are preferably used to produce the nucleating solution. Palladium compounds such as palladium acetate and palladium chloride are already used for metallization.

Both the conventional cis-diamino-di(pseudo) halogeno or alkenyl complexes of Pt(II) or Pd(II) are suitable as complexes, since they contain groups which are suitable for the reaction. Triphosphino complexes of Pd and Pt already contain the metal in oxidation state 0, thus considerably simplifying the formation of nuclei or clusters and promoting this formation of nuclei or clusters at modified surfaces. The ligand systems can be modified very easily (sulfonation, amination, e.g. 3-[bis(3-sulfophenyl) phosphino] benzene sulfonic acid; 1, 3, 5-triaza-7-phosphatricyclo [3,3,1,1] decane), so that it is also possible to obtain species with a suitably adapted charge. The complexes are obtained simply by mixing the ligand with a salt solution of the metal/metals.

Suitable solvents are water and organic solvents and also mixtures. Isopropanol, ethanol, γ-butyrolactone, butanone, N-methylpyrrolidone, acetone, cyclohexanone, cyclopentanone, tetrahydrofuran, ethoxyethyl propionate, ethoxyethyl acetate, ethyl acetate or butyl acetate are particularly suitable. The solution may also contain surfactants (ionic and/or non-ionic surfactants) or amines (e.g. triethylamine or tetramethylammonium hydroxide).

The process is particularly advantageous because numerous electronic and/or microelectronic components are already coated with a buffer coating (for example, wafers from the front-end region, in this form; the buffer coating is, for example, polyimide or polybenzoxazole; beneath this are, for example, the inorganic passivation layers silicon nitride and/or silicon oxide). This buffer coating may already be a first insulating layer in the context of the invention, i.e. it can be activated after the application and patterning of the second layer according to one embodiment of the process.

With the foregoing and other objects in view there is also provided, in accordance with the invention, an electronic or microelectronic component, that includes: a substrate; and a plurality of insulating layers including at least an upper insulating layer and a lower insulating layer which adjoin one another. The plurality of insulating layers have a layer thickness between 0.05 and 50 μm. A layer selected from the group consisting of the upper insulating layer and the lower insulating layer is metallized using the inventive process described herein above.

Other features which are considered as characteristic for the invention are set forth in the appended claims.

Although the invention is illustrated and described herein as embodied in a process for metallizing at least one insulating layer of a component, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1a shows a cross section through a configuration with two activatable insulating layers and one non-activatable insulating layer;

FIG. 1b shows the configuration illustrated in FIG. 1a after activation, nucleation, and metalization;

FIG. 2 shows a cross section through multilayer wiring; and

FIG. 3 shows metalization of a substrate over a plurality of insulating layers.

### DESCRIPTION OF THE PREFERRED EMBODIMENTS

The invention is to be explained in more detail below with reference to exemplary embodiments.

### EXAMPLE 1

A photosensitive polyimide is applied to a silicon substrate using a horizontal centrifuge at 5000 rpm. The centrifuging time is 20 s. The film is then predried for 3 min at 100° C. on a heating plate and is then tempered (hardened) in a nitrogen-purged furnace for 30 min at 400° C. After cooling to room temperature, a photosensitive polybenzoxazole (PBO) is centrifuged onto the polyimide layer, followed by drying on a hotplate, exposure using an exposure unit by means of a mask and development in an aqueous alkaline solution, rinsing and drying. The substrate is tempered on a hotplate using the following ramp: 10° C./min up to 150° C., 5° C./min up to 280° C., holding time 10 min. This is followed by cooling to room temperature. The PBO serves as a mask for the polyimide. To activate the polyimide, the substrate is then immersed for 10 min in an alkaline permanganate solution which is at a temperature of 40° C. and comprises 140 g/l sodium permanganate and 50 g/l sodium hydroxide, is rinsed with deionized water and is then immersed in a 5 mol/l sulfuric acid for 3 min. After rinsing with deionized water, the substrate, for nucleation of the polyimide with a precious metal, is immersed for 4 min in a commercially available ionogenic palladium solution which is at a temperature of 40° C. Reduction using an alkaline sodium borohydride solution (1 g/l sodium borohydride, 5 g/l sodium hydroxide), immersion time 3 min, is then carried out. Finally, a homogeneous, securely adhering layer of copper is obtained on the polyimide by immersion in a chemical copper bath (30 min).

### EXAMPLE 2

The same as for Example 1, except that after nucleation has taken place, the immersion is in a nickel bath. A homogeneous, securely adhering layer of nickel is formed.

### EXAMPLE 3

Similar to Example 1, except that the activation of the polyimide takes place by a short plasma-etching step using oxygen in a reactive ion etcher (30 sccm oxygen, 500W, 70 mTorr, 10 s) with subsequent conditioning by immersion for 3 minutes in a commercially available conditioning bath. This may, for example, be a 0.5 molar sodium hydroxide solution in water.

### EXAMPLE 4

A photosensitive PBO is centrifuged onto a substrate with a silicon nitride surface, is dried on a hotplate and is then tempered (hardened) on a high-temperature hotplate under nitrogen at 350° C. After cooling to room temperature, a polyimide is centrifuged onto the PBO layer, followed by drying on a hotplate. The polyimide is exposed in pattern form using an exposure unit and is developed, is rinsed (isopropanol, isopropanol/deionized water (1:1) and finally deionized water) and then dried. To harden the polyimide, the substrate is tempered in a nitrogen-purged furnace for 60 min at 350° C. After cooling to room temperature, for activation of the polyimide the substrate is immersed for 10 min in a 1.5% by weight strength sodium hydroxide solution which is at a temperature of 40° C., is rinsed with deionized water and is then immersed in a semi-concentrated sulfuric acid for 3 min. The nucleation and metallization take place as described in Example 1.

### EXAMPLE 5

PBO is centrifuged onto a substrate and tempered as in Example 4. Using the screen-printing process, a cyclothene layer (benzocyclobutene, BCB) is applied to the PBO layer and is heated at 250° C. for 30 min. The BCB is activated by immersing the substrate in a 1.5% strength sodium hydroxide solution at 40° C. for 5 min. After rinsing, the substrate is immersed in a commercially available palladium solution for 3 min, is dried, is irradiated with UV light of a wavelength of 254 nm (dose: 150 mJ/cm²), is rinsed with large amounts of water and is dried. The metallization then takes place as described in Example 1.

### EXAMPLE 6

A photosensitive polyimide is centrifuged onto a substrate, followed by drying at 110° C. for 2 min and tempering for 90 min at 350° C. As masking for the selective activation of the polyimide and to reduce its gas and vapor permeability, a 0.5 μm thick amorphous hydrocarbon layer is deposited using a perforated mask by a CVD (Chemical Vapor Deposition) process. This is followed by the activation and metallization as in Example 1.

### EXAMPLE 7

A silicon nitride layer is deposited on a substrate by a PECVD process. Then, a photosensitive polyimide is centrifuged on (5000 rpm, 20 s, 3 min), followed by drying at 100° C. on a hotplate and exposure, in patterned form, with a mask aligner (exposure dose: 250 mJ/cm², development, rinsing (isopropanol, isopropanol/deionized water (1:1) and finally deionized water), followed by drying and tempering as described in Example 1. The selective activation and the metallization take place as described under Example 1.

### EXAMPLE 8

As for Example 7, except that silicon oxide is deposited instead of the silicon nitride.

### EXAMPLE 9

A polyimide is centrifuged onto a silicon substrate (20 s at 5000 rpm), then dried (3 min at 100° C. on a hotplate) and tempered at 350° C. for 30 min on a hotplate. After cooling to room temperature, a different, photosensitive polyimide is centrifuged on, is dried at 90° C., is exposed, developed, rinsed (isopropanol, isopropanol/deionized water (1:1) and then finally deionized water) dried and tempered at 400° C. The non-photosensitive polyimide, which forms the lower layer, is activated and metallized as follows: immersion (10 min) in a 1.5% strength sodium hydroxide solution which is at a temperature of 45° C., rinsing with deionized water followed by immersion in a 1M HCl solution at 30° C. for 30 min, followed by rinsing again with deionized water. Then, the substrate is immersed in a commercially available palladium bath (4 min) and reduced using an alkaline sodium borohydride solution (1 g/l sodium borohydride, 5 g/l sodium hydroxide) for 3 min. The chemical copper plating takes place by immersion for 20 min in a copper bath which is at a temperature of 45° C. A securely adhering, homogeneous layer of copper is obtained.

### EXAMPLE 10

A wafer with a layer of polyimide (“substrate”) which has already been cyclized and is 4 μm thick is wired as follows: Using a CVD process, a water-impermeable silicon nitride layer (50 nm) is applied to this substrate, and the nitride layer is patterned with the aid of a photoresist (exposure and development of the photoresist, dry chemical etching of the nitride layer using CHF₃/O₂, plasma stripping of the photresist). Plasma etching is stopped at the polyimide layer lying beneath it. The plasma etching results in an activated surface to which the palladium complex can be selectively bonded by immersion in a solution of 200 mg η²-bipyridyl-η²4,4′-diaminostilbenopalladium (II) in 500 ml of isopropanol. This is followed by reduction using an alkaline sodium borohydride solution (1 g/l sodium borohydride, 5 g/l sodium hydroxide) for 2 min. There then follows the chemical copper plating by immersion for 45 min in a commercially available copper bath. A securely adhering, homogeneous layer of copper is obtained.

### EXAMPLE 11

Analogous to Example 10, except that the palladium complex is reduced photochemically, so as to form a cyclobutane derivative and palladium (0). A polychromatic light source (Hg high-pressure lamp) is used for this floodlighting (300 mJ/cm²).

### EXAMPLE 12

A substrate similar to that in Example 10, to which the oxide layer is applied in ready-patterned form, i.e. via a perforated mask, by means of an X-ray mask. The exposed polyimide is activated by immersion (1 min) in concentrated nitric acid at 50° C.

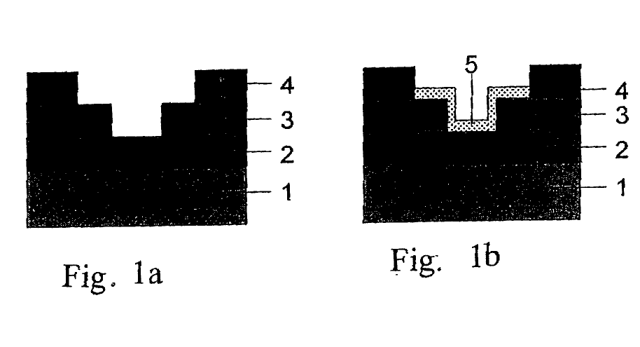

Referring now to the figures of the drawing in detail and first, particularly, to FIGS. 1a and 1b thereof, there is shown a configuration (cross section through an electronic or microelectronic component) with two activatable and one non-activatable insulating layers.

FIG. 1a shows a cross section without metallization. The figure shows the substrate 1, to which the following layers are applied: the first activatable insulating layer 2, which is not patterned, and the second activatable insulating layer 3, which is patterned. Above this is the third insulating layer 4, which is not activatable.

The finished layer structure from FIG. 1a is subjected to activation, nucleation and metallization, then resulting in a layer structure as can be seen in FIG. 1b: the metal 5 lies on top of the two activatable layers 2 and 3 and the surface of the non-activatable layer 4 is free of metal.

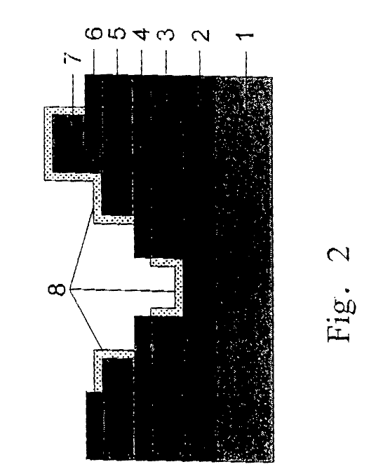

FIG. 2 shows a cross section through multilayer wiring. The layer structure is as follows:

Right at the bottom is the substrate 1, to which a first insulating layer 2, which is activatable, is applied in unpatterned form. This layer is adjoined by a second activatable layer 3, which is provided with a hole, and on which there lies a non-activatable layer 4, which likewise has the same hole structure. The non-activatable layer 4 is adjoined by an activatable insulating layer 5 which is patterned, as is the subsequent non-activatable layer 6. The structure of the layers 5 and 6 is not identical, so that there are regions in which the surface of the layer 5 is exposed. Yet another activatable layer 8 is applied to the layer 6, and this activatable layer 8 in turn has a different structure from the two layers which lie beneath it. During the subsequent metallization with the metallic layer 7, both the hole in layer 3 (exposed surfaces of the layers 2 and 3; the metallized hole and the insulating layer 3 are consequently at the same “level”) and the exposed surface of the layers 5 and 7 are metallized.

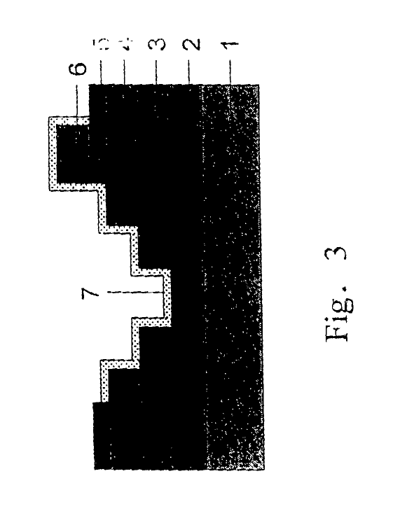

FIG. 3 shows metallization of a substrate over a plurality of insulating layers:

The insulating layers 2, 3, 4, 5 and 6 are applied to a substrate 1. The insulating layers 3, 4, 5 and 6 are in each case patterned after the application or deposited in pattern form. The insulating layers 2, 3, 4 and 6 can be activated simultaneously, but the layer 5 cannot. The finished layer structure is subjected to activation, nucleation and metallization. The exposed surfaces of the layers 2, 3, 4 and 6 are metallized: metal layer 7.

We claim:

1. A process for metallizing at least one insulating layer of an electronic or microelectronic component, which comprises:
applying at least a first insulating layer to a substrate;
applying at least a second insulating layer to at least the first insulating layer;
patterning at least the second insulating layer;
selectively activating an exposed and activatable surface to obtain exposed activated regions;
nucleating and metallizing the exposed, activated regions.

2. The process according to claim 1, which comprises:
providing a plurality of insulating layers which includes the first insulating layer and the second insulating layer; and
providing each one of the plurality of the insulating layers with a layer thickness of at most 50 μm.

3. The process according to claim 1, which comprises:
providing a plurality of insulating layers which includes the first insulating layer and the second insulating layer;
providing one of the plurality of the insulating layers as an activatable layer; and
providing another one of the plurality of the insulating layers as a non activatable layer.

4. The process according to claim 1, which comprises:
providing a plurality of insulating layers which includes the first insulating layer and the second insulating layer; and
wherein the step of selectively activating the exposed and activatable surface includes activating individual ones of the plurality of the insulating layers at various levels.

5. The process according to claim 1, wherein the step of selectively activating the exposed and activatable surface includes a plurality of activating steps.

6. The process according to claim 1, which comprises using a plurality of activators to perform the step of selectively activating the exposed and activatable surface.

7. The process according to claim 1, which comprises patterning the first insulating layer.

8. The process according to claim 1, which comprises applying at least a further insulating layer to at least the second insulating layer.

9. The process according to claim 1, which comprises patterning the further insulating layer.

10. An electronic or microelectronic component, comprising:
a substrate; and
a plurality of insulating layers including at least an upper insulating layer and a lower insulating layer which adjoin one another;
said plurality of insulating layers having a layer thickness between 0.05 and 50 μm;
a layer selected from the group consisting of said upper insulating layer and said lower insulating layer being metallized using the process according to claim 1.
